(19) United States
(12) Patent Application Publication
(10) Pub. No.: US 2026/0301623 A1
(43) Pub. Date: Oct. 1, 2026

(54) DISPLAY DEVICE AND DISPLAY METHOD THEREFOR

(71) Applicant: HKC CORPORATION LIMITED, Shenzhen, Guangdong (CN)

(72) Inventors: Yao Li, Shenzhen, Guangdong (CN); Zhonglin Cao, Shenzhen, Guangdong (CN); Chuan Wu, Shenzhen, Guangdong (CN); Lidan Ye, Shenzhen, Guangdong (CN)

(21) Appl. No.: 19/476,714

(22) PCT Filed: Aug. 7, 2023
(86) PCT No.: PCT/CN2023/111546

§ 371 Date: Oct. 20, 2025

(30) Foreign Application Priority Data
Apr. 28, 2023 (CN) 202310476786.3

(51) Int. Cl. G09G 3/00; G09G 3/20; H10D 86/40; H10D 86/60

(52) U.S. Cl. CPC G09G 3/035; G09G 3/2092; G09G 2300/0452; G09G 2310/08; G09G 2340/0407; H10D 86/441; H10D 86/60

(57) ABSTRACT

A display device includes a stretchable display panel and a control circuit. The stretchable display panel includes a stretchable substrate and pixel islands including first pixels. Along a first direction, a respective one of second pixels is adjacently arranged at a same side of each of the first pixels so as to form one of a plurality of pixel groups. The second pixels are made of deformable materials. The control circuit is configured to control, when the stretchable display panel is in a display state, the driving voltages of each of the first pixels and the respective one of the second pixels in the same pixel group to be input at a same timing sequence in a case where the stretchable display panel is not stretched, and to be input in different timing sequences in a case where the stretchable display panel is stretched.

### CROSS-REFERENCE TO RELATED APPLICATIONS

This application is the U.S. national phase of International Application No. PCT/CN2023/111546 with an international filing date of Aug. 7, 2023, designating the U.S., now pending, and claims the priority of the Chinese patent application submitted to the CNIPA on Apr. 28, 2023, with an application number 202310476786.3 and titled “DISPLAY DEVICE AND DISPLAY METHOD THEREFOR”, the entire contents of which are incorporated by reference in this application.

### BACKGROUND

### Technical Field

The present application relates to the field of display technology, more particularly to a display device and a display method therefor.

### Description of Related Art

With the development of the display industry, conventional rigid display screens can no longer meet the actual use requirements of multiple scenarios, and flexible stretchable display screens are increasingly attracting the attention of consumers due to their variable display size and adaptability to a variety of scenarios. Currently, by forming display pixel units, connecting wires, light-emitting units, and other components on a flexible substrate, a stretchable display device that can be stretched/contracted in a specific direction and changed to a fixed shape can be formed. When the display screen of the stretchable display device is stretched, the distance between the pixels included in the display pixel unit will increase, thereby reducing the resolution of the display screen, resulting in different resolutions of the display screen before and after stretching, which in turn leads to a worse user experience when viewing the display screen.

### SUMMARY

It is one of objects of embodiments of the present application to provide a display device and a display method therefor. By arranging a respective second pixel on the same side of each first pixel along a first direction, and constructing the second pixel to be stretchable, when the stretchable display panel is stretched, the area of each second pixel becomes larger, thereby solving the problem that the resolution of the existing stretchable display screen decreases after stretching, which would otherwise result in different resolutions before and after stretching of the display screen and affect the user experience when viewing the display screen.

In order to solve the above technical problems, embodiments of the present application provide the following technical solutions:

A first aspect of embodiments of the present application provides a display device. The display device comprises a stretchable display panel and a control circuit. The stretchable display panel comprises a stretchable substrate and pixel islands arranged in an array in a form of rows and columns on the stretchable substrate. The pixel islands comprise first pixels. Along a first direction, a respective one of second pixels is adjacently arranged at a same side of each of the first pixels so as to form one of a plurality of pixel groups, and each of the first pixels and the respective one of the second pixels in a same pixel group have a same luminous color. The first direction refers to a stretchable direction of the stretchable display panel. The second pixels are made of deformable materials. A stretch sensing module is also arranged on the stretchable substrate, and the stretch sensing module is in electric connection with the control circuit, the stretch sensing module is configured to sense a stretching degree of the stretchable substrate to determine whether each of the second pixels is stretched to a target area size. The control circuit is configured to: control driving voltages of each of the first pixels and the respective one of the second pixels in the same pixel group to be input at a same timing sequence when the stretchable display panel is not stretched and is in a display state and the stretch sensing module determines that each of the second pixels is not stretched to the target area size, and control the driving voltages of each of the first pixels and the respective one of the second pixels in the same pixel group to be input in different timing sequences when the stretchable display panel is stretched in the first direction and is in the display state and the stretch sensing module determines that each of the second pixels is stretched to the target area size.

In an embodiment of the present application, the first direction is a column direction, a respective one row of the second pixels are arranged at a same side of each row of the first pixels in the column direction; each of the first pixels and the respective one of the second pixels in the same pixel group are located in a same column.

The control circuit is configured to: control driving voltages of the first pixels and the second pixels in adjacent rows to be input at a same timing sequence when the stretchable display panel is not stretched and is in the display state and the stretch sensing module determines that each of the second pixels is not stretched to the target area size, and control the driving voltages of the first pixels and the second pixels in adjacent rows to be input in different timing sequences when the stretchable display panel is stretched in the column direction and is in the display state and the stretch sensing module determines that each of the second pixels is stretched to the target area size.

In an embodiment of the present application, along the column direction, a size of each of the second pixels is smaller than a size of each of the first pixels in the same column.

In an embodiment of the present application, along a row direction, a size of each of the second pixels is equal to a size of each of the first pixels in the same column.

In an embodiment of the present application, each of the second pixels in the same row has a same size in the column direction.

In an embodiment of the present application, the first pixels in each row are connected together by connecting lines and connected to a first gate driving circuit, and the second pixels in each row are connected together by connecting lines and connected to a second gate driving circuit.

Both the first gate driving circuit and the second gate driving circuit are in electric connection with the control circuit, the first gate driving circuit is configured to scan the first pixels row by row along the column direction, and the second gate driving circuit is configured to scan the second pixels row by row along the column direction.

In an embodiment of the present application, the first direction is a row direction, a respective one row of the second pixels are arranged at a same side of each row of the first pixels in the row direction. Each of the first pixels and the respective one of the second pixels in the same pixel group are located in a same row.

The control circuit is configured to: control driving voltages of the first pixels and the second pixels in a same row to be input at a same timing sequence when the stretchable display panel is not stretched and is in the display state and the stretch sensing module determines that each of the second pixels is not stretched to the target area size, and control the driving voltages of the first pixels and the second pixels in the same row to be input in different timing sequences when the stretchable display panel is stretched in the row direction and is in the display state and the stretch sensing module determines that each of the second pixels is stretched to the target area size.

In an embodiment of the present application, along the row direction, a size of each of the second pixels is smaller than a size of each of the first pixels in the same row.

In an embodiment of the present application, along the column direction, a size of each of the second pixels is equal to a size of each of the first pixels in the same row.

In an embodiment of the present application, each of the second pixels in the same column has a same size in the row direction.

In an embodiment of the present application, the first pixels in the same row are connected together by connecting lines and connected to a first gate driving circuit, and the second pixels in the same row are connected together by connecting lines and connected to a second gate driving circuit.

Both the first gate driving circuit and the second gate driving circuit are in electric connection with the control circuit, the first gate driving circuit is configured to scan the first pixels row by row along the column direction, and the second gate driving circuit is configured to scan the second pixels row by row along the column direction.

In an embodiment of the present application, along the first direction, a second pixel located between adjacent two of the first pixels is located at a middle of the adjacent two of the first pixels.

In an embodiment of the present application, the stretchable substrate is also provided with at least one wire extending along the first direction, the at least one wire is in electric connection with the control circuit, and the control circuit is also configured to detect a resistance of the at least one wire, and determine whether the stretchable substrate is stretched in the first direction and whether each of the second pixels is stretched to a target area size according to a change in a resistance value of the at least one wire.

A second aspect of embodiments of the present application provides a display method for a display device. The display device is the display device according to the above embodiments, and the display method comprises:
obtaining a state of the stretchable display panel and determining whether each of the second pixels is stretched to the target area size;
controlling driving voltages of the first pixels and the second pixels in adjacent rows to be input at a same timing sequence when the stretchable display panel is not stretched and is in the display state and the stretch sensing module determines that each of the second pixels is not stretched to the target area size; and
controlling the driving voltages of the first pixels and the second pixels in adjacent rows to be input in different timing sequences when the stretchable display panel is stretched in the column direction and is in the display state and the stretch sensing module determines that each of the second pixels is stretched to the target area size.

A third aspect of embodiments of the present application provides a display method for a display device. The display device is the display device according to the above embodiments, and the display method comprises:
obtaining a state of the stretchable display panel and determining whether each of the second pixels is stretched to the target area size;
controlling driving voltages of the first pixels and the second pixels in a same row to be input at a same timing sequence when the stretchable display panel is not stretched and is in the display state and the stretch sensing module determines that each of the second pixels is not stretched to the target area size; and
controlling the driving voltages of the first pixels and the second pixels in the same row to be input in different timing sequences when the stretchable display panel is stretched in the row direction and is in the display state and the stretch sensing module determines that each of the second pixels is stretched to the target area size.

Compared with the prior art, in the display device provided in the first aspect of the embodiments of the present application, a respective one of second pixels is arranged at a same side of each of the first pixels along a first direction so as to form the pixel group. When the stretchable display panel is not stretched in the display state, each second pixel has a small area, and each first pixel and the respective second pixel in the same pixel group are displayed as a whole. When the stretchable display panel is stretched in the first direction in the display state, the second pixel is stretched and the area becomes larger, so that each first pixel and the respective second pixel in the same pixel group can be displayed separately. In this way, although the distance between two adjacent first pixels in the first direction becomes larger due to the stretching of the stretchable display panel, the compensatory display of the second pixel ensures that the number of luminous pixels per unit area will not be reduced too much, thereby reducing the phenomenon of resolution decrease after the stretchable display panel is stretched in the first direction, so that the resolutions of the display panel before and after stretching are similar, thereby improving the user experience.

It can be understood that the beneficial effects of the second and third aspects mentioned above can be referred to the relevant description in the first aspect in the above, and will not be repeated herein.

### BRIEF DESCRIPTION OF THE DRAWINGS

In order to more clearly illustrate the technical solutions in the embodiments of the present application, the drawings that need to be used in the description of the embodiments will be briefly described hereinbelow. Obviously, the accompanying drawings in the following description are only some embodiments of the present application. For those skilled in the art, other drawings can be obtained based on these drawings without creative work.

FIG. 1 is a structural schematic diagram of a display device provided in Example 1 of the present application;

FIG. 2 is a structural schematic diagram of a stretchable display panel of the display device provided in Example 1 of the present application when not stretched;

FIG. 3 is a structural schematic diagram of a stretchable display panel of the display device provided in Example 1 of the present application after being stretched;

FIG. 4 is a cascade diagram of a driving voltage input of first pixels and second pixels of the stretchable display panel of the display device provided in Example 1 of the present application;

FIG. 5 is a driving voltage input timing diagram of the first pixels and the second pixels in FIG. 4 when the stretchable display panel of the display device provided in Example 1 of the present application is not stretched;

FIG. 6 is a driving voltage input timing diagram of the first pixels and the second pixels in FIG. 4 when the stretchable display panel of the display device provided in Example 1 of the present application is stretched;

FIG. 7 is a structural schematic diagram of a stretchable display panel of the display device provided in Example 2 of the present application when not stretched;

FIG. 8 is a structural schematic diagram of a stretchable display panel of the display device provided in Example 2 of the present application after being stretched;

FIG. 9 is a cascade diagram of a driving voltage input of first pixels and second pixels of the stretchable display panel of the display device provided in Example 2 of the present application;

FIG. 10 is a driving voltage input timing diagram of the first pixels and the second pixels in FIG. 9 when the stretchable display panel of the display device provided in Example 2 of the present application is not stretched;

FIG. 11 is a driving voltage input timing diagram of the first pixels and the second pixels in FIG. 9 when the stretchable display panel of the display device provided in Example 2 of the present application is stretched;

FIG. 12 is a schematic flow chart of a display method for a display device provided in Example 3 of the present application; and

FIG. 13 is a schematic flow chart of a display method for a display device provided in Example 4 of the present application.

In the drawings, the following reference numerals are adopted: 100, stretchable display panel; 200, control circuit;
1, stretchable substrate; 2, pixel island; 20, first pixel;
3, second pixel; 10, pixel group; and
4, stretch sensing module.

### DETAILED DESCRIPTION OF THE EMBODIMENTS

In order to make the objects, technical solutions, and advantages of the present application clearer, the present application is further described in detail in combination with the accompanying drawings and embodiments. It should be understood that the specific embodiments described herein are only used to explain the present application and are not intended to limit the present application.

It should be noted that when an element is referred to as “fixed on” or “arranged on” another element, the element can be directly on the other element or indirectly on the other element. When an element is referred to as “connected to” another element, the element can be directly connected to the other element or indirectly connected to the other element.

It should be understood that the orientation or position relationship indicated by the terms “length”, “width”, “upper”, “lower”, “front”, “back”, “left”, “right”, “vertical”, “horizontal”, “top”, “bottom”, “inside”, “outside” and the like are based on the orientation or position relationship shown in the accompanying drawings, and is only for the convenience of describing the present application and simplifying the description, rather than indicating or implying that the device or element referred to must have a specific orientation, be constructed and operated in a specific orientation, and therefore cannot be understood as a restriction on the present application.

In addition, the terms “first” and “second” are only used for descriptive purposes and cannot be understood as indicating or implying relative importance or implicitly indicating the number of technical features indicated. Thus, a feature defined as “first” or “second” may explicitly or implicitly include one or more of the features. In the description of this application, “plurality” means two or more, unless otherwise clearly and specifically defined.

It should also be noted that the same reference numerals are used in the embodiments of the present application to represent the same components or the same parts. For the same parts in the embodiments of the present application, one of the parts or components in the figures are marked as an example. It should be understood that the reference numerals are also applicable to other identical parts or components.

Embodiments of the present application provide a display device and a display method therefor, which tackles the problem that the resolution of the existing stretchable display screen decreases after stretching, resulting in different resolutions of the display screen before and after stretching, thereby affecting the user experience when viewing the display screen.

### Example 1

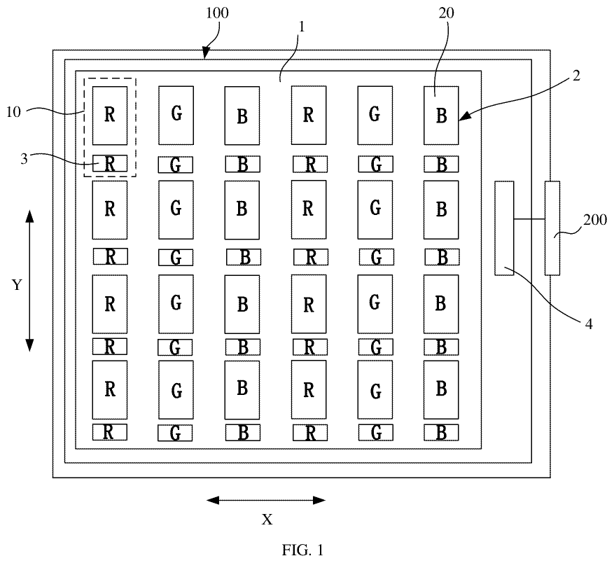

Referring to FIG. 1, a display device provided in embodiments of the present application includes a stretchable display panel 100 and a control circuit 200. The stretchable display panel 100 includes a stretchable substrate 1 and a plurality of pixel islands 2 arranged in an array in the form of rows and columns on the stretchable substrate 1. The plurality of pixel islands 2 includes first pixels 20. The first pixels 20 are pixels R, G, and B as shown in FIG. 1. Each of the plurality of pixel islands 2 may include a rigid substrate and a first pixel 20 arranged on the rigid substrate. The rigid substrates may be made of a rigid material, and the rigid substrates are arranged on the stretchable substrate 1. In this way, when the stretchable substrate 1 is stretched, only the positions in contact with the rigid substrates do not deform, and all other positions of the stretchable substrate 1 are deformed. Since the first pixels 20 are located on the rigid substrates, when the stretchable substrate 1 is stretched, the first pixels 20 do not deform and areas thereof do not change.

Along a first direction, a respective one of second pixels 3 is adjacently arranged at a same side of each of the first pixels 20 so as to form one of a plurality of pixel groups 10, and each of the first pixels 20 and the respective one of the second pixels 3 in a same pixel group 10 have a same luminous color. The first direction refers to a stretchable direction of the stretchable display panel 100. The second pixels 3 are made of deformable materials. The control circuit 200 is configured to: control driving voltages of each of the first pixels 20 and the respective one of the second pixels 3 in the same pixel group 10 to be input at a same timing sequence when the stretchable display panel 100 is not stretched and is in a display state, and control the driving voltages of each of the first pixels 20 and the respective one of the second pixels 3 in the same pixel group 10 to be input in different timing sequences when the stretchable display panel 100 is stretched in the first direction and is in the display state.

It should be noted that along the first direction, a respective one of second pixels 3 is adjacently arranged at a same side of each of the first pixels 20 so as to form one of a plurality of pixel groups 10, that is, each of the first pixels 20 is provided with a respective one of second pixels 3, and each of the first pixels 20 and the respective one of second pixels 3 form a pixel group. When the stretchable display panel 100 is not stretched and is in the display state, the driving voltages of each of the first pixels 20 and the respective one of the second pixels 3 in the same pixel group 10 are controlled to be input at the same timing sequence. Since the area of each second pixel 3 is small when not being stretched, that is, the first pixel 20 and the second pixel 3 in the same pixel group 10 are displayed as a whole and are input with driving voltages at the same timing sequence, such that the first pixel 20 and the second pixel 3 in the same pixel group 10 emit light simultaneously. When the stretchable display panel 100 is stretched in the first direction and is in the display state, the driving voltages of each of the first pixels 20 and the respective one of the second pixels 3 in the same pixel group 10 are controlled to be input in different timing sequences, that is, the driving voltages of each of the first pixels 20 and the respective one of the second pixels 3 in the same pixel group 10 are input in different timing sequences. Since the area of each second pixel 3 becomes larger after stretching, the first pixel 20 and the second pixel 3 in the same pixel group 10 need to be displayed separately.

Through the above arrangement, although the distance between two adjacent first pixels 20 in the first direction becomes larger due to the stretching of the stretchable display panel 100, the compensatory display of the second pixel 3 ensures that the number of luminous pixels per unit area will not be reduced too much, thereby reducing the phenomenon of resolution decrease after the stretchable display panel 100 is stretched in the first direction, so that the resolutions of the display panel before and after stretching are similar, thereby improving the user experience.

When it is referred to that the stretchable display panel 100 is not stretched and is in the display state, it means that the stretchable display panel 100 is in a natural state, and the stretchable substrate 1 and the second pixels 3 are not subjected to any stretching force in any direction. When it is referred to that the stretchable display panel 100 is stretched in the first direction and is in the display state, it means that after the stretchable display panel 100 is stretched, the area of each second pixel 3 is stretched to the target area size, and the target area size can be set according to the specific display situation, but it is necessary to ensure that each second pixel 3 of the target area size can be displayed as an independent pixel. For example, the size of the second pixel 3 in the first direction in embodiments of the present application can be set to 8 to 12 microns when it is not stretched, so that the second pixel 3 can be stretched to an independently displayable pixel for display within the stretchable range of the stretchable display panel 100.

In some embodiments, a stretch sensing module 4 is also arranged on the stretchable substrate 1, and the stretch sensing module 4 is in electric connection with the control circuit 200, the stretch sensing module 4 is configured to sense a stretching degree of the stretchable substrate 1. In this way, a stretching degree of each of the second pixels 3 can be determined by the stretching degree of the stretchable substrate sensed by the stretch sensing module 4, and it is determined whether each of the second pixels 3 is stretched to the target area size, so as to determine whether the stretchable display panel 100 is stretched and in the display state, and accurately control the driving voltages of the first pixel 20 and the second pixel 3 in the same pixel group 10 to be input in different timing sequences, such that it can be avoided the problems that the area of the second pixel 3 has not reached the target area size while the first pixel 20 and the second pixel 3 are input with the driving voltages in different timing sequences, which would otherwise result in uneven brightness of the second pixel 3 and the first pixel 20 on the display panel and affect the display effect.

It should be noted that the stretch sensing module 4 in the embodiments of the present application is only for sensing the stretching degree of the stretchable substrate 1, so as to determine the stretching degree of each of the second pixels 3 according to the stretching degree of the stretchable substrate and to determine whether the area of each of the second pixels 3 reaches the target area size, so as to input the driving voltages to the first pixel 20 and the second pixel 3 in the same pixel group 10 in different timing sequences. Therefore, the specific structure of the stretch sensing module 4 is not specifically limited in this application.

In some embodiments, the stretchable substrate 1 is also provided with at least one wire extending along the first direction. The at least one wire is in electric connection with the control circuit 200, and the control circuit 200 is also configured to detect a resistance of the at least one wire. When the resistance of the wire increases from an initial value to a first threshold value, the control circuit 200 is also configured to determine that the stretchable substrate 1 is stretched in the first direction, that is, the stretchable display panel 100 is stretched in the first direction, in such condition, each of the second pixels 3 is stretched to the target area size. The control circuit 200 can control the driving voltages of the first pixel 20 and the second pixel 3 in the same pixel group 10 to be input in different timing sequences.

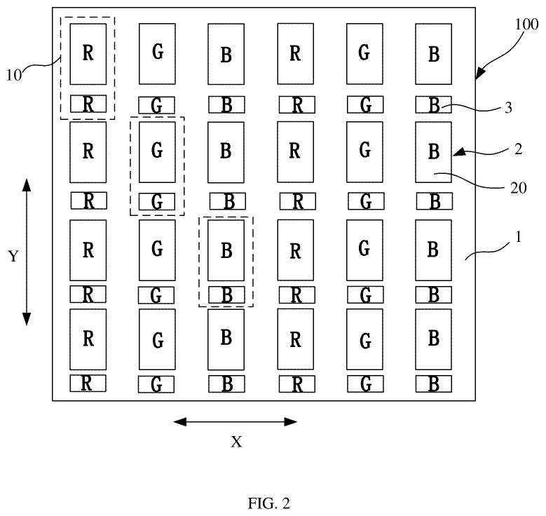

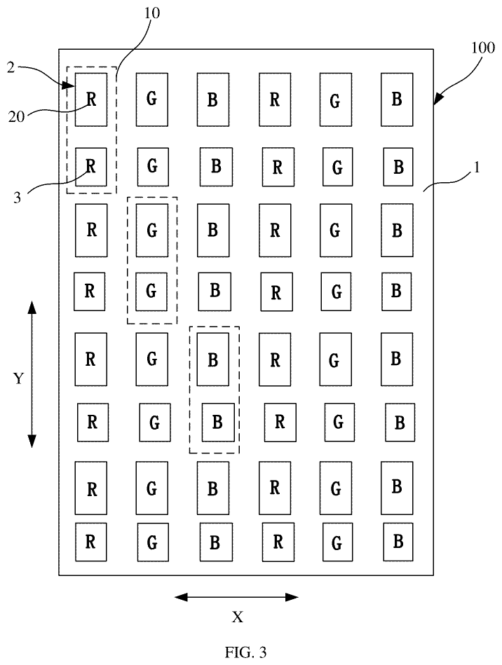

In some embodiments, referring to FIG. 2-FIG. 3, the first direction is a column direction Y, a respective one row of the second pixels 3 are arranged at a same side of each row of the first pixels 20 in the column direction Y. Each of the first pixels 20 and the respective one of the second pixels 3 in the same pixel group 10 are located in a same column. The control circuit 200 is configured to: control driving voltages of the first pixels 20 and the second pixels 3 in adjacent rows to be input at a same timing sequence when the stretchable display panel 100 is not stretched and is in the display state, and control the driving voltages of the first pixels 20 and the second pixels 3 in adjacent rows to be input in different timing sequences when the stretchable display panel 100 is stretched in the column direction Y and is in the display state.

In this way, at the same side of each row of the first pixels 20 in the multiple rows of the first pixels arranged in the column direction Y, a respective one row of the second pixels 3 are arranged. When the stretchable display panel 100 is stretched in the column direction Y, the second pixels 3 will also be enlarged. In such condition, the second pixels 3 will be displayed as independent pixels. The control circuit 200 will input the driving voltages to the first pixels 20 and the second pixels 3 in different timing sequences, so that the number of pixels per unit area in such condition is slightly different from the number of pixels per unit area when the stretchable display panel 100 is not stretched, thereby avoiding a significant impact on the resolution and not reducing the display effect of the stretchable display panel 100.

It should be noted that, referring to FIG. 2-FIG. 3, the stretchable direction of the stretchable display panel 100 is the column direction Y, and each row of first pixels 20 is provided with a respective one row of second pixels 3 on the same side in the column direction Y, so that each first pixel 20 can be ensured to be provided with a corresponding second pixel 3, and the luminous colors of each of the first pixels 20 and the respective one of second pixels 3 are the same. When the stretchable display panel 100 is not stretched, each of the first pixels 20 will be displayed simultaneously with a respective one of second pixels 3 as a whole, which can ensure that the overall display brightness of the stretchable display panel 100 is more even. When the stretchable display panel 100 is stretched, since the number of rows of the second pixels 3 is the same as the number of rows of the first pixels 20, it can be ensured that the distribution of pixels at different locations on the stretchable display panel 100 is relatively even, and it can be ensured that the number of pixels per unit area changes slightly, which will not have the problem of poor display effect caused by different resolutions before and after the stretching of the stretchable display panel 100.

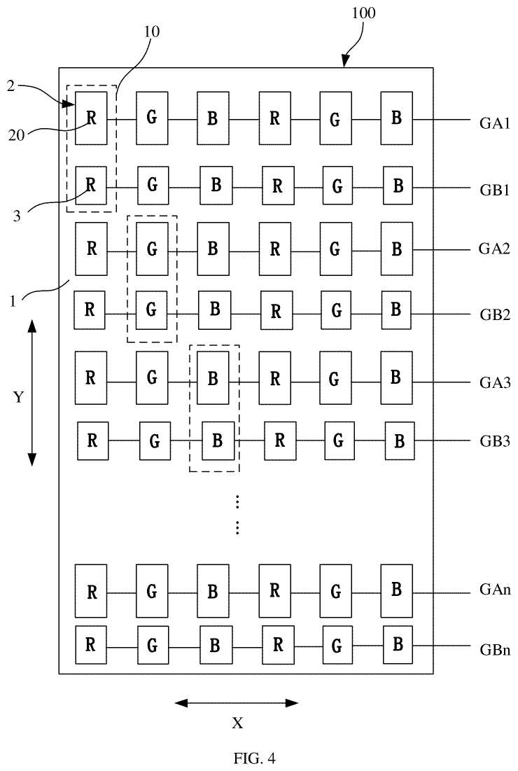

Specifically, referring to FIG. 4, the first pixels 20 in each row can be connected together by connecting lines, and the first pixels 20 connected together in each row can be connected to the first gate driving circuit, and the second pixels 3 in each row can also be connected together by connecting lines, and the second pixels 3 connected together in each row can be connected to the second gate driving circuit, and both the first gate driving circuit and the second gate driving circuit are in electric connection with the control circuit 200, and the first gate driving circuit is configured to scan the first pixels 20 row by row along the column direction Y, and the second gate driving circuit is configured to scan the second pixels 3 row by row along the column direction Y. GA1 in FIG. 4 represents the first pixels 20 of a first row scanned, GAn represents the first pixel 20 of an nth row scanned, GB1 represents the second pixel 3 of a first row scanned, and GBn represents the second pixel 3 of an nth row scanned.

In some embodiments, a conventional GOA model can be configured to input driving voltages to each scanned stage, such as the common 23T1C/21T1C/11T1C and other models.

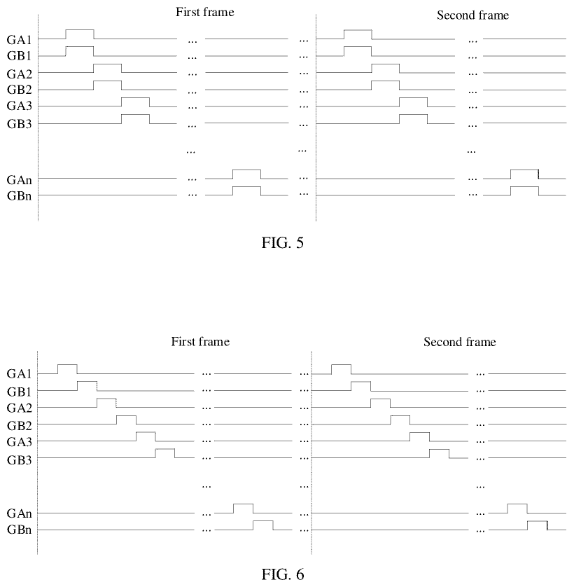

When the stretchable display panel 100 is not stretched and is in the display state, the control circuit 200 controls the first pixels 20 and the second pixels 3 to be input with the driving voltages at the same timing sequence. Specifically, as shown in FIG. 5, the first gate driving circuit scans the first pixels of the first row GA1 and the second gate driving circuit scans the second pixels of the first row GB1 simultaneously, and the control circuit 200 simultaneously inputs the same driving voltage to the scanned GA1 and GB1. Then, the first pixels of the second row GA2 and the second pixels of the second row GB2 are simultaneously scanned, and the control circuit 200 simultaneously inputs the same driving voltage to the scanned GA2 and GB2. The similar steps are performed until the last rows are scanned. In this way, the first pixel 20 of the first row and the second pixel 3 of the first row are driven to emit light simultaneously. Since the second pixel 3 has a small area when it is not stretched and the display effect is small, the second pixel 3 and the first pixel 20 together can be displayed as a whole simultaneously, which not only does not affect the resolution, but also enhances the display brightness of the display panel, thereby being conducive to improving the display effect.

When the stretchable display panel 100 is stretched in the column direction Y and is in the display state, the control circuit 200 controls the first pixels 20 and the second pixels to be input with the driving voltages in different timing sequences. Specifically, as shown in FIG. 6, first, the first gate driving circuit scans the first pixels of the first row GA1, and the control circuit 200 inputs a driving voltage to the scanned first pixels of the first row GA1. Then, the second gate driving circuit scans the second pixels of the first row GB1, and the control circuit 200 inputs a driving voltage to the scanned second pixels of the first row GB1. Then, the first gate driving circuit scans the first pixels of the second row GA2, and the control circuit 200 inputs a driving voltage to the scanned first pixels of the second row GA2. The driving voltage is input according to an order of GA1, GB1, GA2, GB2, . . . , GAn, GBn, so that each row of second pixels 3 are displayed separately from each row of first pixels 20. For example, four rows of first pixels 20 and four rows of second pixels 3 are provided. When the second pixels 3 are stretched and enlarged, the area of each second pixel 3 is slightly different from the area of each first pixel 20. The pixels that can be displayed separately on the stretchable substrate 1 are equivalent to eight rows of pixels. The eight rows of pixels are scanned in turn, followed with the input of the driving voltage. This not only makes the pixels of the display panel evenly distributed and displayed, but also the number of pixels per unit area will not change too much, so that the resolution of the stretchable display panel 100 before and after stretching is not much different, and will not affect the display effect of the stretchable display panel 100.

In embodiments of the present application, two independent GOA models are adopted to input signals to the first pixels 20 and the second pixels 3 respectively. Alternatively, one GOA model can also be configured to input signals to the first pixels 20 and the second pixels 3. Specifically, when the stretchable display panel 100 is not stretched and is in the display state, one GOA model is adopted to input signals to the first pixels 20 and the second pixels 3 simultaneously, so that each of the first pixels 20 and the respective one of the second pixels 3 in the same pixel group 10 are displayed as a whole and emit light simultaneously. When the stretchable display panel 100 is stretched in the column direction Y and is in the display state, one GOA model is adopted to input signals to each of the first pixels 20 and the respective one of the second pixels 3 in the same pixel group 10. It should be noted that another GOA model for timing control in different timing sequences is needed to input signals to each of the first pixels 20 and the respective one of the second pixels 3 in the same pixel group 10 in different timing sequences to ensure that the timing sequences of the driving voltage input of the first pixels 20 and the second pixels 3 reach the timing sequences as shown in FIGS. 5-6.

In some embodiments, referring to FIG. 2-FIG. 3, along the column direction Y, a size of each of the second pixels 3 is smaller than a size of each of the first pixels 20 in the same column. Along a row direction X, a size of each of the second pixels 3 is equal to a size of each of the first pixels 20 in the same column. In this way, each second pixel 3 can have a smaller area when not being stretched, and can be displayed as a whole with the corresponding first pixel 20. After stretching, the area of each of the second pixels 3 can be approximately the same as that of each of the first pixels 20, and the second pixels 3 can be displayed separately, thereby ensuring that the number of pixels per unit area is not reduced much, and the resolution of the stretchable display panel 100 before and after stretching is not much different, which will not affect the display effect.

It should be noted that, since the stretchable direction of the stretchable display panel 100 is the column direction Y, the size of each second pixel 3 in the column direction Y can be enlarged by stretching, while the size of each second pixel 3 in the row direction X remains unchanged. Therefore, it is required to construct the size of each second pixel 3 in the row direction X to be the same as the size of each first pixel 20 in the same column in the row direction X, and construct the size of each second pixel 3 in the column direction Y to be smaller than the size of each first pixel 20 in the same column in the column direction Y. In this way, when the second pixel 3 is stretched, the size of the second pixel 3 in the column direction Y will become larger, so that the area of the second pixel 3 remains substantially the same as the area of the first pixel 20 in the same column.

In some embodiments, referring to FIG. 3, each of the second pixels 3 in the same row has a same size in the column direction Y. In this way, the area of the second pixels 3 in the same row after stretching can be the same, so that the first pixels 20 and the second pixels 3 are evenly distributed, thereby producing a better display effect of the entire display panel.

In the Example 1 of the present application, along the first direction, a second pixel 3 located between adjacent two of the first pixels 20 is located at a middle of the adjacent two of the first pixels 20. That is, along the column direction Y, a row of second pixels 3 located between two adjacent rows of the first pixels are located in middle position of two adjacent rows of the first pixels 20. In this way, after the second pixels 3 are stretched, each of the second pixels 3 with enlarged areas is equally spaced apart from the adjacent two of the first pixels 20, thereby making the distribution of the first pixels 20 and the second pixels 3 more even and being conducive to the improvement of the display effect.

### Example 2

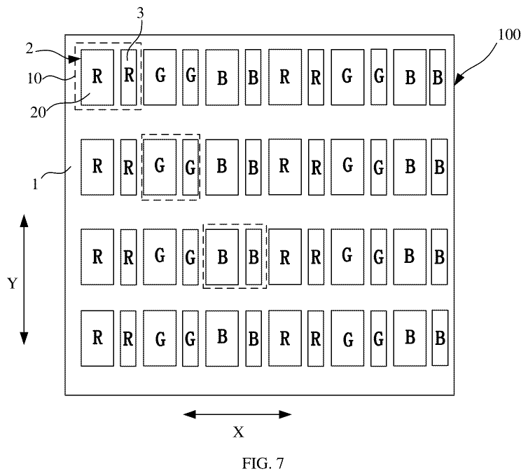

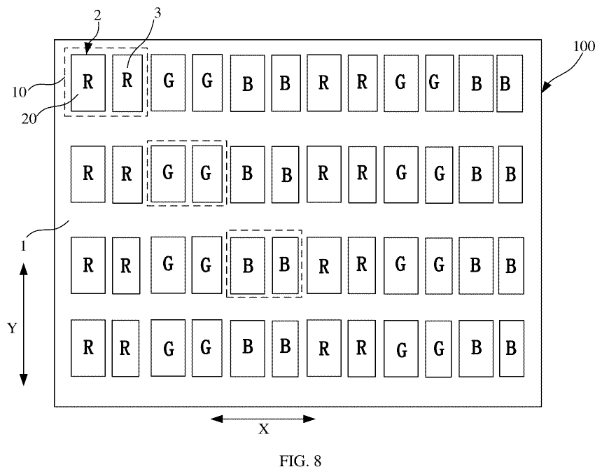

Referring to FIGS. 7-8, the display device provided in Example 2 of the present application is only different from that in Example 1 in that the stretchable direction of the stretchable display panel 100 is different. In Example 2 of the present application, the first direction is a row direction X. A respective one row of the second pixels 3 are arranged at a same side of each row of the first pixels 20 in the row direction X; each of the first pixels 20 and the respective one of the second pixels 3 in the same pixel group 10 are located in a same row. The control circuit 200 is configured to: control driving voltages of the first pixels 20 and the second pixels 3 in a same row to be input at a same timing sequence when the stretchable display panel 100 is not stretched and is in the display state, and control the driving voltages of the first pixels 20 and the second pixels 3 in the same row to be input in different timing sequences when the stretchable display panel 100 is stretched in the row direction X and is in the display state.

In this way, at the same side of each column of the first pixels 20 in the multiple columns of the first pixels arranged in the row direction X, a respective one column of the second pixels 3 are arranged. When the stretchable display panel 100 is stretched in the row direction X, the second pixels 3 will also be enlarged. In such condition, the second pixels 3 will be displayed as independent pixels. The control circuit 200 will input the driving voltages to the first pixels 20 and the second pixels 3 in different timing sequences, so that the number of pixels per unit area in such condition is slightly different from the number of pixels per unit area when the stretchable display panel 100 is not stretched, thereby avoiding a significant impact on the resolution and not reducing the display effect of the stretchable display panel 100.

It should be noted that, referring to FIG. 7-FIG. 8, the stretchable direction of the stretchable display panel 100 is the row direction X, and each column of first pixels 20 is provided with a respective one column of second pixels 3 on the same side in the row direction X, so that each first pixel 20 can be ensured to be provided with a corresponding second pixel 3, and the luminous colors of each of the first pixels 20 and the respective one of second pixels 3 are the same. When the stretchable display panel 100 is not stretched, each of the first pixels 20 will be displayed simultaneously with a respective one of second pixels 3 as a whole, which can ensure that the overall display brightness of the stretchable display panel 100 is more even. When the stretchable display panel 100 is stretched, since the number of columns of the second pixels 3 is the same as the number of columns of the first pixels 20, it can be ensured that the distribution of pixels at different locations on the stretchable display panel 100 is relatively even, and it can be ensured that the number of pixels per unit area changes slightly, which will not have the problem of poor display effect caused by different resolutions before and after the stretching of the stretchable display panel 100.

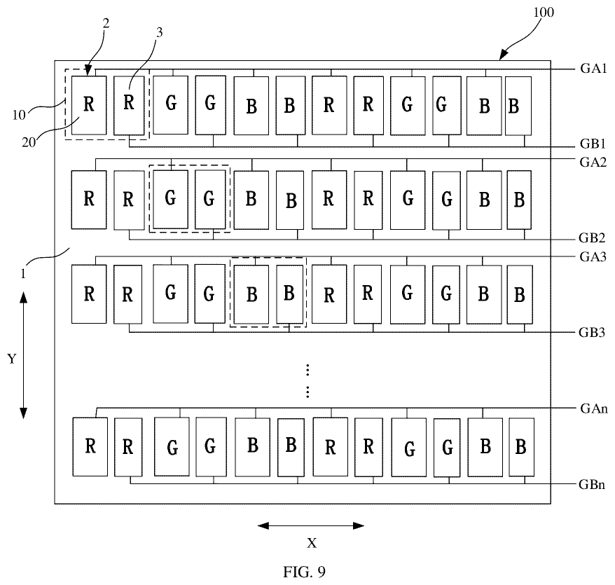

Specifically, referring to FIG. 9, the first pixels 20 in the same row can be connected together by connecting lines, and the first pixels 20 connected together in each row can be connected to the first gate driving circuit, and the second pixels 3 in the same row can also be connected together by connecting lines, and the second pixels 3 connected together in each row can be connected to the second gate driving circuit, and both the first gate driving circuit and the second gate driving circuit are in electric connection with the control circuit 200, and the first gate driving circuit is configured to scan the first pixels 20 row by row along the column direction Y, and the second gate driving circuit is configured to scan the second pixels 3 row by row along the column direction Y. GA1 in FIG. 9 represents the first pixels 20 of a first row scanned, GAn represents the first pixel 20 of an nth row scanned, GB1 represents the second pixel 3 of a first row scanned, and GBn represents the second pixel 3 of an nth row scanned.

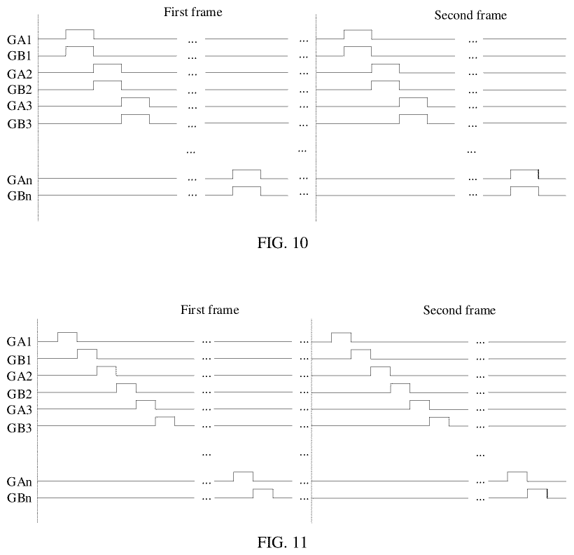

When the stretchable display panel 100 is not stretched and is in the display state, the control circuit 200 controls the first pixels 20 and the second pixels 3 to be input with the driving voltages at the same timing sequence. Specifically, as shown in FIG. 10, the first gate driving circuit scans the first pixels of the first row GA1 and the second gate driving circuit scans the second pixels of the first row GB1 simultaneously, and the control circuit 200 simultaneously inputs the same driving voltage to the scanned GA1 and GB1. Then, the first pixels of the second row GA2 and the second pixels of the second row GB2 are simultaneously scanned, and the control circuit 200 simultaneously inputs the same driving voltage to the scanned GA2 and GB2. The similar steps are performed until the last rows are scanned. In this way, the first pixel 20 of the first row and the second pixel 3 of the first row are driven to emit light simultaneously. Since the second pixel 3 has a small area when it is not stretched and the display effect is small, the second pixel 3 and the first pixel 20 together can be displayed as a whole simultaneously, which not only does not affect the resolution, but also enhances the display brightness of the display panel, thereby being conducive to improving the display effect.

When the stretchable display panel 100 is stretched in the column direction Y and is in the display state, the control circuit 200 controls the first pixels 20 and the second pixels to be input with the driving voltages in different timing sequences. Specifically, as shown in FIG. 11, first, the first gate driving circuit scans the first pixels of the first row GA1, and the control circuit 200 inputs a driving voltage to the scanned first pixels of the first row GA1. Then, the second gate driving circuit scans the second pixels of the first row GB1, and the control circuit 200 inputs a driving voltage to the scanned second pixels of the first row GB1. Then, the first gate driving circuit scans the first pixels of the second row GA2, and the control circuit 200 inputs a driving voltage to the scanned first pixels of the second row GA2. The driving voltage is input according to an order of GA1, GB1, GA2, GB2, . . . , GAn, GBn, so that the second pixels 3 and the first pixels 20 of the same row are displayed separately. For example, four columns of first pixels 20 and four columns of second pixels 3 are provided. A total number of pixels are arranged into four rows. Each row includes the first pixels 20 and the second pixels 3. When the second pixels 3 are stretched and enlarged, the area of each second pixel 3 is slightly different from the area of each first pixel 20. The pixels that can be displayed separately on the stretchable substrate 1 are equivalent to pixels arranged in four rows and eight columns. The first pixels 20 in the first row are scanned firstly, then the second pixels 3 in the first row are scanned. Thereafter, the first pixels 20 in the second row are scanned, and then the second pixels 3 in the second row are scanned. According to this scanning order, the four rows of pixels are scanned and the driving voltage is input in sequence. This not only makes the pixels of the display panel evenly distributed and displayed, but also the number of pixels per unit area will not change too much, so that the resolution of the stretchable display panel 100 before and after stretching is not much different, and will not affect the display effect of the stretchable display panel 100.

In some embodiments, referring to FIG. 7-FIG. 8, along the row direction X, a size of each of the second pixels 3 is smaller than a size of each of the first pixels 20 in the same row. Along the column direction Y, a size of each of the second pixels 3 is equal to a size of each of the first pixels 20 in the same row. In this way, each second pixel 3 can have a smaller area when not being stretched, and can be displayed as a whole with the corresponding first pixel 20. After stretching, the area of each of the second pixels 3 can be approximately the same as that of each of the first pixels 20, and the second pixels 3 can be displayed separately, thereby ensuring that the number of pixels per unit area is not reduced much, and the resolution of the stretchable display panel 100 before and after stretching is not much different, which will not affect the display effect.

It should be noted that, since the stretchable direction of the stretchable display panel 100 is the row direction X, the size of each second pixel 3 in the row direction X can be enlarged by stretching, while the size of each second pixel 3 in the column direction Y remains unchanged. Therefore, it is required to construct the size of each second pixel 3 in the column direction Y to be the same as the size of each first pixel 20 in the same row in the column direction Y, and construct the size of each second pixel 3 in the row direction X to be smaller than the size of each first pixel 20 in the same row in the row direction X. In this way, when the second pixel 3 is stretched, the size of the second pixel 3 in the row direction X will become larger, so that the area of the second pixel 3 remains substantially the same as the area of the first pixel 20 in the same column.

In some embodiments, referring to FIG. 8, each of the second pixels 3 in the same column has a same size in the row direction X. In this way, the area of the second pixels 3 in the same column after stretching can be the same, so that the first pixels 20 and the second pixels 3 are evenly distributed, thereby producing a better display effect of the entire display panel.

In the Example 2 of the present application, along the first direction, a second pixel 3 located between adjacent two of the first pixels 20 is located at a middle of the adjacent two of the first pixels 20. That is, along the row direction X, a column of second pixels 3 located between two adjacent columns of the first pixels are located in middle position of two adjacent columns of the first pixels 20. In this way, after the second pixels 3 are stretched, each of the second pixels 3 with enlarged areas is equally spaced apart from the adjacent two of the first pixels 20, thereby making the distribution of the first pixels 20 and the second pixels 3 more even and being conducive to the improvement of the display effect.

### Example 3

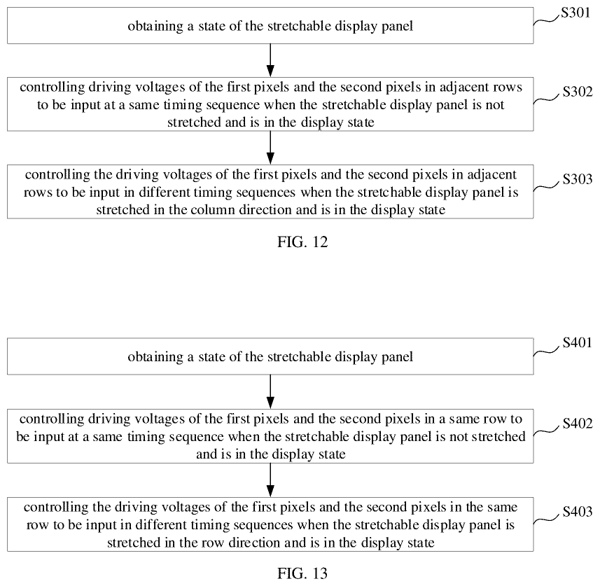

Referring to FIG. 12, Example 3 of the present application provides a display method for a display device, the display device is a display device as described in Example 1 in the above, and the display method are performed by the following steps:

In step S301, a state of the stretchable display panel 100 is obtained.

Specifically, the stretching degree of the stretchable substrate 1 can be sensed by the stretch sensing module 4 provided on the stretchable substrate 1. Since the second pixels 3 are arranged on the stretchable substrate 1, the second pixels 3 will produce a stretching phenomenon as the stretchable substrate 1 is stretched. The stretching degree of each of the second pixels 3 can be obtained according to the stretching degree of the stretchable display substrate, thereby obtaining the state of the stretchable display panel 100. It should be noted that as long as the area of each second pixel 3 after being stretched does not reach the target area size, it means that the state of the stretchable display panel 100 is not stretched and is in the display state. When the area of each second pixel 3 after being stretched reaches the target area size, it means that the state of the stretchable display panel 100 is stretched and is in the display state.

In step S302, when the stretchable display panel 100 is not stretched and is in the display state, driving voltages of the first pixels 20 and the second pixels 3 in adjacent rows are controlled to be input at a same timing sequence.

In step S303, when the stretchable display panel 100 is stretched in the column direction Y and is in the display state, driving voltages of the first pixels 20 and the second pixels 3 in adjacent rows are controlled to be input in different timing sequences.

Through the display method provided in the Example 3 of the present application, when the stretchable display panel 100 is not stretched in the display state, each second pixel 3 has a small area, and each first pixel 20 and the respective second pixel 3 in the same pixel group 10 are displayed as a whole. When the stretchable display panel 100 is stretched in the first direction in the display state, the second pixel 3 is stretched and the area becomes larger, so that each first pixel 20 and the respective second pixel 3 in the same pixel group 10 can be displayed separately. In this way, although the distance between two adjacent first pixels 20 in the first direction becomes larger due to the stretching of the stretchable display panel 100, the compensatory display of the second pixel 3 ensures that the number of luminous pixels per unit area will not be reduced too much, thereby reducing the phenomenon of resolution decrease after the stretchable display panel 100 is stretched in the first direction, so that the resolutions of the display panel before and after stretching are similar, thereby reducing the screen display granularity.

### Example 4

Referring to FIG. 13, Example 4 of the present application provides a display method for a display device, the display device is the display device as described in Example 2 in the above, and the display method comprises:
S401, obtaining a state of the stretchable display panel 100;
S402, controlling driving voltages of the first pixels 20 and the second pixels 3 in a same row to be input at a same timing sequence when the stretchable display panel 100 is not stretched and is in the display state; and
S403, controlling the driving voltages of the first pixels 20 and the second pixels 3 in the same row to be input in different timing sequences when the stretchable display panel 100 is stretched in the row direction and is in the display state.

The above description is only specific embodiments of the present application, but the protection scope of the present application is not limited thereto. Those skilled in the art can easily think of changes or replacements within the technical scope disclosed in the present application, which should be included within the protection scope of the present application. Therefore, the protection scope of the present application shall be subject to the protection scope of the claims.

What is claimed is:

1. A display device, comprising a stretchable display panel and a control circuit, the stretchable display panel comprising a stretchable substrate and pixel islands arranged in an array in a form of rows and columns on the stretchable substrate, and the pixel islands comprise first pixels, wherein
along a first direction, a respective one of second pixels is adjacently arranged at a same side of each of the first pixels so as to form one of a plurality of pixel groups, and each of the first pixels and the respective one of the second pixels in a same pixel group have a same luminous color; the first direction refers to a stretchable direction of the stretchable display panel;
the second pixels are made of deformable materials;
a stretch sensing module is also arranged on the stretchable substrate, and the stretch sensing module is in electric connection with the control circuit, the stretch sensing module is configured to sense a stretching degree of the stretchable substrate to determine whether each of the second pixels is stretched to a target area size; and
the control circuit is configured to:
control driving voltages of each of the first pixels and the respective one of the second pixels in the same pixel group to be input at a same timing sequence when the stretchable display panel is not stretched and is in a display state and the stretch sensing module determines that each of the second pixels is not stretched to the target area size, and
control the driving voltages of each of the first pixels and the respective one of the second pixels in the same pixel group to be input in different timing sequences when the stretchable display panel is stretched in the first direction and is in the display state and the stretch sensing module determines that each of the second pixels is stretched to the target area size.

2. The display device according to claim 1, wherein
the first direction is a column direction, a respective one row of the second pixels are arranged at a same side of each row of the first pixels in the column direction;
each of the first pixels and the respective one of the second pixels in the same pixel group are located in a same column; and
the control circuit is configured to:
control driving voltages of the first pixels and the second pixels in adjacent rows to be input at a same timing sequence when the stretchable display panel is not stretched and is in the display state and the stretch sensing module determines that each of the second pixels is not stretched to the target area size, and
control the driving voltages of the first pixels and the second pixels in adjacent rows to be input in different timing sequences when the stretchable display panel is stretched in the column direction and is in the display state and the stretch sensing module determines that each of the second pixels is stretched to the target area size.

3. The display device according to claim 2, wherein
along the column direction a size of each of the second pixels is smaller than a size of each of the first pixels in the same column.

4. The display device according to claim 3, wherein
along a row direction, a size of each of the second pixels is equal to a size of each of the first pixels in the same column.

5. The display device according to claim 4, wherein
each of the second pixels in the same row has a same size in the column direction

6. The display device according to claim 2, wherein
the first pixels in each row are connected together by connecting lines and connected to a first gate driving circuit, and the second pixels in each row are connected together by connecting lines and connected to a second gate driving circuit; and
both the first gate driving circuit and the second gate driving circuit are in electric connection with the control circuit, the first gate driving circuit is configured to scan the first pixels row by row along the column direction, and the second gate driving circuit is configured to scan the second pixels row by row along the column direction.

7. The display device according to claim 1, wherein
the first direction is a row direction, a respective one row of the second pixels are arranged at a same side of each row of the first pixels in the row direction; each of the first pixels and the respective one of the second pixels in the same pixel group are located in a same row; and
the control circuit is configured to:
control driving voltages of the first pixels and the second pixels in a same row to be input at a same timing sequence when the stretchable display panel is not stretched and is in the display state and the stretch sensing module determines that each of the second pixels is not stretched to the target area size, and
control the driving voltages of the first pixels and the second pixels in the same row to be input in different timing sequences when the stretchable display panel is stretched in the row direction and is in the display state and the stretch sensing module determines that each of the second pixels is stretched to the target area size.

8. The display device according to claim 7, wherein
along the row direction, a size of each of the second pixels is smaller than a size of each of the first pixels in the same row.

9. The display device according to claim 8, wherein
along the column direction, a size of each of the second pixels is equal to a size of each of the first pixels in the same row.

10. The display device according to claim 9, wherein
each of the second pixels in the same column has a same size in the row direction.

11. The display device according to claim 7, wherein
the first pixels in the same row are connected together by connecting lines and connected to a first gate driving circuit, and the second pixels in the same row are connected together by connecting lines and connected to a second gate driving circuit; and
both the first gate driving circuit and the second gate driving circuit are in electric connection with the control circuit, the first gate driving circuit is configured to scan the first pixels row by row along the column direction, and the second gate driving circuit is configured to scan the second pixels row by row along the column direction.

12. The display device according to claim 1, wherein
along the first direction, a second pixel located between adjacent two of the first pixels is located at a middle of the adjacent two of the first pixels.

13. The display device according to claim 1, wherein
the stretchable substrate is also provided with at least one wire extending along the first direction, the at least one wire is in electric connection with the control circuit, and the control circuit is also configured to detect a resistance of the at least one wire, and determine whether the stretchable substrate is stretched in the first direction and whether each of the second pixels is stretched to a target area size according to a change in a resistance value of the at least one wire.

14. A display method for a display device, wherein the display device is the display device according to claim 2, and the display method comprises:
obtaining a state of the stretchable display panel and determining whether each of the second pixels is stretched to the target area size;
controlling driving voltages of the first pixels and the second pixels in adjacent rows to be input at a same timing sequence when the stretchable display panel is not stretched and is in the display state and the stretch sensing module determines that each of the second pixels is not stretched to the target area size; and
controlling the driving voltages of the first pixels and the second pixels in adjacent rows to be input in different timing sequences when the stretchable display panel is stretched in the column direction and is in the display state and the stretch sensing module determines that each of the second pixels is stretched to the target area size.

15. A display method for a display device, wherein the display device is the display device according to claim 7, and the display method comprises:
obtaining a state of the stretchable display panel and determining whether each of the second pixels is stretched to the target area size;
controlling driving voltages of the first pixels and the second pixels in a same row to be input at a same timing sequence when the stretchable display panel is not stretched and is in the display state and the stretch sensing module determines that each of the second pixels is not stretched to the target area size; and
controlling the driving voltages of the first pixels and the second pixels in the same row to be input in different timing sequences when the stretchable display panel is stretched in the row direction and is in the display state and the stretch sensing module determines that each of the second pixels is stretched to the target area size.

16. The display device according to claim 5, wherein
the first pixels in each row are connected together by connecting lines and connected to a first gate driving circuit, and the second pixels in each row are connected together by connecting lines and connected to a second gate driving circuit; and
both the first gate driving circuit and the second gate driving circuit are in electric connection with the control circuit, the first gate driving circuit is configured to scan the first pixels row by row along the column direction, and the second gate driving circuit is configured to scan the second pixels row by row along the column direction.

17. The display device according to claim 10, wherein,
the first pixels in the same row are connected together by connecting lines and connected to a first gate driving circuit, and the second pixels in the same row are connected together by connecting lines and connected to a second gate driving circuit; and
both the first gate driving circuit and the second gate driving circuit are in electric connection with the control circuit, the first gate driving circuit is configured to scan the first pixels row by row along the column direction, and the second gate driving circuit is configured to scan the second pixels row by row along the column direction.

18. The display method according to claim 14, wherein
along the column direction, a size of each of the second pixels is smaller than a size of each of the first pixels in the same column.

19. The display method according to claim 18, wherein
along a row direction, a size of each of the second pixels is equal to a size of each of the first pixels in the same column.

20. The display method according to claim 19, wherein
each of the second pixels in the same row has a same size in the column direction.
